(19) United States
(12) Patent Application Publication
(10) Pub. No.: US 2025/0343213 A1
(43) Pub. Date: Nov. 6, 2025

(54) ELECTRONIC DEVICE

(71) Applicant: Advanced Semiconductor Engineering, Inc., Kaohsiung (TW)

(72) Inventors: Chien-Mei HUANG, Kaohsiung (TW); I-Ting LIN, Kaohsiung (TW); Sheng-Wen YANG, Kaohsiung (TW)

(73) Assignee: Advanced Semiconductor Engineering, Inc., Kaohsiung (TW)

(21) Appl. No.: 18/656,565

(22) Filed: May 6, 2024

(51) Int. Cl. H01L 25/16; H01L 23/00; H01L 23/31; H01L 23/48; H01L 23/498

(52) U.S. Cl. CPC H01L 25/16; H01L 23/3107; H01L 23/481; H01L 23/49811; H01L 23/49822; H01L 24/08; H01L 24/16; H01L 2224/08265; H01L 2224/16227

(57) ABSTRACT

An electronic device is provided. The electronic device includes a carrier having a first conductive element, an electronic component, and a second conductive element. The first conductive element is exposed by a lower surface of the carrier. The electronic component is disposed over the carrier and configured to receive a power from the first conductive element. The second conductive element is disposed at a lateral side of the carrier and protruding downwardly below the lower surface of the carrier.

### BACKGROUND

### 1. Field of the Disclosure

The present disclosure relates to an electronic device, and particularly to an electronic device integrating an electronic component and a passive element.

### 2. Description of the Related Art

In an electronic device, when a passive element is integrated with an electronic component, the distance therebetween and the size of the passive element can impact the performance of the passive element. However, it is difficult to satisfy requirements for both a shorter distance and a greater size of the passive element. In order to enhance the performance of the passive element, a new electronic device is thus required.

### SUMMARY

In some embodiments, an electronic device includes a carrier having a first conductive element, an electronic component, and a second conductive element. The first conductive element is exposed by a lower surface of the carrier. The electronic component is disposed over the carrier and configured to receive a power from the first conductive element. The second conductive element is disposed at a lateral side of the carrier and protruding downwardly below the lower surface of the carrier.

In some embodiments, an electronic device includes a carrier having a first conductive element, an electronic component, and a second conductive element. The first conductive element is exposed by a lower surface of the carrier. The electronic component is disposed over the carrier and configured to receive a power from the first conductive element. The second conductive element is disposed at a lateral side of the carrier. A lower surface of the first conductive element and a lower surface of the second conductive element are in different elevations with respect to the lower surface of the carrier.

In some embodiments, an electronic device includes a passive component, an electronic component, a first redistribution structure, and a second redistribution structure. The passive component has a lower surface and an upper surface opposite to the lower surface. The electronic component is disposed over the upper surface of the passive component and has a backside surface and an active surface opposite to the backside surface. The first redistribution structure is directly connected to the lower surface of the passive component. The second redistribution structure is directly connected to the active surface of the electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an example of an electronic device according to some embodiments of the present disclosure.

FIG. 1B is a partial enlarged view of the electronic device shown in FIG. 1A according to some embodiments of the present disclosure.

FIG. 1C is a partial enlarged view of the electronic device shown in FIG. 1A according to some embodiments of the present disclosure.

FIG. 1D is a partial enlarged view of the electronic device shown in FIG. 1A according to some embodiments of the present disclosure.

FIG. 2 is a partial enlarged view of the electronic device shown in FIG. 1A according to some embodiments of the present disclosure.

FIG. 3 is a partial enlarged view of the electronic device shown in FIG. 1A according to some embodiments of the present disclosure.

FIG. 4 illustrates a cross-sectional view of an example of an electronic device according to some embodiments of the present disclosure.

FIG. 5 illustrates a cross-sectional view of an example of an electronic device according to some embodiments of the present disclosure.

FIG. 6 illustrates a cross-sectional view of an example of an electronic device according to some embodiments of the present disclosure.

FIG. 7 illustrates a cross-sectional view of an example of an electronic device according to some embodiments of the present disclosure.

FIG. 8 illustrates a cross-sectional view of an example of an electronic device according to some embodiments of the present disclosure.

FIGS. 9A, 9B, 9C, 9D, 9E, 9F, and 9G illustrate various stages of an example of a method for manufacturing an electronic device according to some embodiments of the present disclosure.

FIGS. 10A, 10B, 10C, 10D, 10E, and 10F illustrate various stages of an example of a method for manufacturing an electronic device according to some embodiments of the present disclosure.

FIGS. 11A, 11B, and 11C illustrate various stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

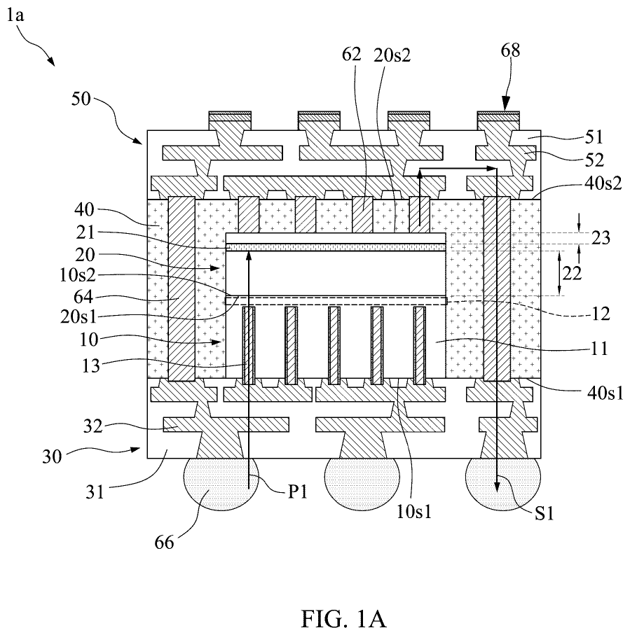

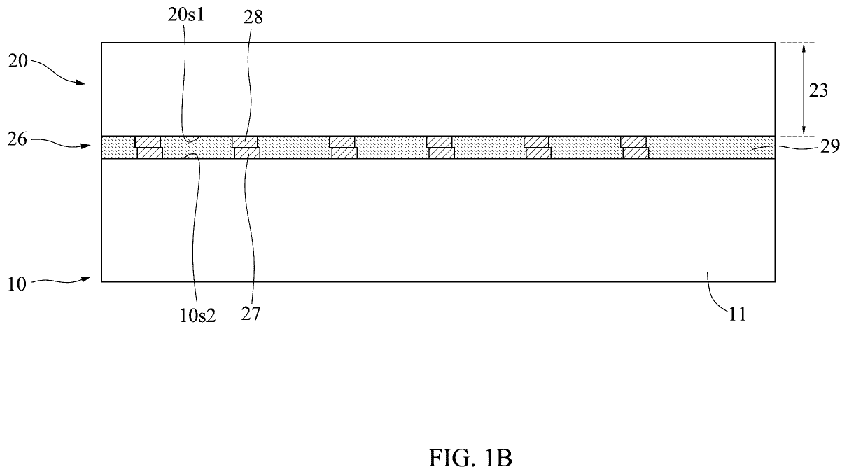

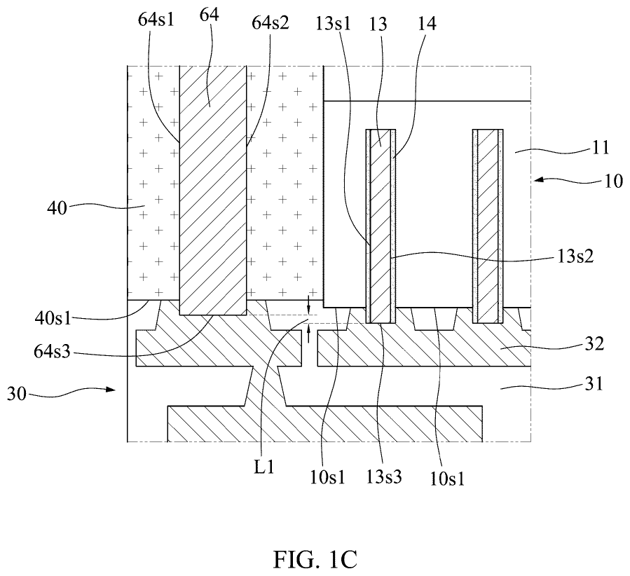

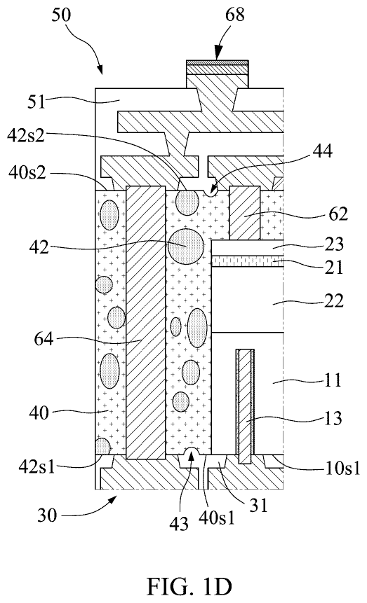

FIG. 1A illustrates a cross-sectional view of an electronic device 1a according to some embodiments of the present disclosure.

In some embodiments, the electronic device 1a may include a carrier 10, an electronic component 20, a redistribution structure 30, an encapsulant 40, and a redistribution structure 50.

In some embodiments, the carrier 10 may be configured to consume, store, and transmit energy. In some embodiments, the carrier 10 may be configured to stabilize, adjust, receive, and/or transmit power. In some embodiments, the carrier 10 may include a passive component, such as capacitor, inductor, resistor, filter, or a combination of such components. The capacitor may include a deep trench capacitor (DTC), a multi-layer ceramic capacitor (MLCC) or other capacitors. The carrier 10 may have a surface 10s1 (or a lower surface) and a surface 10s2 (or an upper surface) opposite to the surface 10s1. The carrier 10 may include a substrate 11, a passive circuit region 12, and conductive elements 13.

The substrate 11 may include a semiconductor substrate. The substrate 11 may include silicon or germanium in a single crystal form, a polycrystalline form, or an amorphous form. The lower surface of the substrate 11 may function as the surface 10s1 of the carrier 10.

The passive circuit region 12 may be embedded in the substrate 11. The passive circuit region 12 may abut the surface 10s2 of the carrier 10. In some embodiments, the passive circuit region 12 may define one or more capacitors and include a metal-insulator-metal (MIM) structure or other suitable structures.

The conductive element 13 may extend between the surface 10s1 of the carrier 10 and the passive circuit region 12. The conductive element 13 may penetrate a portion of the substrate 11. The conductive element 13 may be electrically connected to the passive circuit region 12. In some embodiments, the conductive element 13 may include a through silicon via (TSV). The conductive element 13 may be configured to receive and/or transmit power. The conductive element 13 may include copper, aluminum, gold, silver, tungsten, nickel, a combination thereof or other suitable materials.

In some embodiments, the electronic component 20 may be disposed on or over the surface 10s2 of the carrier 10. The electronic component 20 may include an active component, which may generate and/or process a signal. The active component may include a semiconductor die or a chip, such as a logic die (e.g., application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

The electronic component 20 may have a surface 20s1 (or a lower surface or a backside surface) facing the carrier 10 and a surface 20s2 (or an upper surface or an active surface) opposite to the surface 20s1. The electronic component 20 may have an integrated circuit (IC) layer 21, a redistribution structure 22, and a redistribution structure 23. As used herein, the term “active surface” may refer to a surface through which a signal (e.g., I/O signal) passes.

The IC layer 21 may abut the surface 20s2 of the electronic component 20. The IC layer 21 may include one or more ICs formed within the base, such as a semiconductor substrate. The IC layer 21 may be configured to receive power (or a power signal), and generate a signal (or a non-power signal), such as an input/out (I/O) signal or other signals.

The redistribution structure 22 (or a power delivery network (PDN)) may be disposed between the surface 20s1 and the IC layer 21. In some embodiments, the redistribution structure 22 may be configured to receive and/or transmit power, which may include or be composed of direct current (DC), to the redistribution structure 22. The redistribution structure 22 may include one or more conductive traces and conductive vias embedded within one or more dielectric layers.

The redistribution structure 23 may be disposed between the IC layer 21 and the surface 20s2 of the electronic component 20. The redistribution structure 23 may be configured to receive and/or transmit a signal (e.g., I/O signal), which may include or be composed of alternating current (AC). In some embodiments, the redistribution structure 23 may include one or more conductive traces and conductive vias embedded within one or more dielectric layers.

The redistribution structure 30 may be disposed on or under the surface 10s1 of the carrier 10. In some embodiments, the redistribution structure 30 may be configured to transmit power to the carrier 10. In some embodiments, the redistribution structure 30 may be configured to receive a signal from the electronic component 20. The redistribution structure 30 may include a dielectric structure 31 and a conductive structure 32 within the dielectric structure 31. The dielectric structure 31 may include one or more dielectric layers, which may include or be made of polyimide, polybenzoxazole, benzocyclobuten, or a combination thereof. The conductive structure 32 may include conductive traces, vias, pads, and other conductive elements for electrical connection. In some embodiments, the carrier 10 may be directly connected to the redistribution structure 30. For example, the carrier 10 may be electrically connected to the redistribution structure 30 by a non-solder joint. In some embodiments, the conductive element 13 of the carrier 10 may be directly in contact with the conductive structure 32 of the redistribution structure 30. In some embodiments, no solder materials (or reflowable materials), such as tin or an alloy including tin, are disposed between the surface 10s1 of the carrier 10 and the upper surface of the redistribution structure 30.

In some embodiments, the encapsulant 40 may be disposed on or over the upper surface (not annotated) of the redistribution structure 30. In some embodiments, the encapsulant 40 may encapsulate the carrier 10 and the electronic component 20. In some embodiments, the encapsulant 40 may cover the surface 20s2 of the electronic component 20. The encapsulant 40 may include a novolac-based resin, an epoxy-based resin, a silicone-based resin, or another suitable material. Suitable fillers may also be included, such as powdered SiO₂. In some embodiments, the encapsulant 40 may include a molding compound, which may be formed by a molding technique, such as compression molding, injection molding, or transfer molding. The encapsulant 40 may have a surface 40s1 (or a lower surface) and a surface 40s2 (or an upper surface) opposite to the surface 40s1.

The redistribution structure 50 may be disposed on or over the surface 40s2 of the encapsulant 40. In some embodiments, the redistribution structure 50 may cover the surface 20s2 of the electronic component 20. In some embodiments, the redistribution structure 50 may be configured to receive a signal from the electronic component 20. The redistribution structure 50 may include a dielectric structure 51 and a conductive structure 52 within the dielectric structure 51. The dielectric structure 51 may include one or more dielectric layers, which may include or be made of polyimide, polybenzoxazole, benzocyclobuten, or a combination thereof. The conductive structure 52 may include conductive traces, vias, pads, and other conductive elements for electrical connection.

The semiconductor device 1a may include electrical connectors 62. The electrical connector 62 may be disposed on or over the electronic component 20. The electrical connector 62 may be disposed between the electronic component 20 and the redistribution structure 50. The electrical connector 62 may be encapsulated by the encapsulant 40. In some embodiments, the electronic component 20 may be directly connected to the redistribution structure 50. For example, the electronic component 20 may be electrically connected to the redistribution structure 50 by a non-solder joint. In some embodiments, no solder materials (or reflowable materials), such as tin or an alloy including tin, are disposed between the electronic component 20 and the redistribution structure 50. For example, the electrical connector 62 may be electrically connected to the electronic component 20 and the redistribution structure 50. The electrical connector 62 may include copper, aluminum, gold, silver, tungsten, nickel, a combination thereof or other suitable materials.

The semiconductor device 1a may include conductive elements 64. In some embodiments, the conductive element 64 may electrically connect the redistribution structure 30 and the redistribution structure 50. In some embodiments, the conductive element 64 may penetrate the encapsulant 40. In some embodiments, the conductive element 64 may be encapsulated by the encapsulant 40. In some embodiments, the conductive element 64 may be disposed at a side, which extends between the surface 10s1 and surface 10s2, of the carrier 10. In some embodiments, the dimension (e.g., diameter or width) of the conductive element 64 may be greater than that of the conductive element 13. The conductive element 64 may include a seed layer and a conductive material on the seed layer. The seed layer may include titanium or a derivative of titanium, such as titanium nitride or other suitable materials. The conducive material may include copper, aluminum, gold, silver, tungsten, nickel, a combination thereof or other suitable materials.

The semiconductor device 1a may include electrical connectors 66. The electrical connector 66 may be disposed on or under the lower surface of the redistribution structure 30. The electrical connector 66 may be connected to an external device (not shown). The electrical connector 66 may include a solder ball, such as a controlled collapse chip connection (C4) bump, a ball grid array (BGA), a land grid array (LGA), or so on. In some embodiments, the electrical connector 66 may include a solder material(s), which may include alloys of gold and tin solder or alloys of silver and tin solder, or other suitable materials.

The semiconductor device 1a may include electrical connectors 68. The electrical connector 68 may be disposed on the upper surface of the redistribution structure 50. The electrical connector 68 may be connected to an external device (not shown). The electrical connector 68 may include one or more conductive layers. For example, the electrical connector 68 may include a stacked structure, such as a copper/nickel/gold pad or other suitable structures. In other embodiments, the electrical connector 68 may include a solder ball, such as a controlled collapse chip connection (C4) bump, a ball grid array (BGA), a land grid array (LGA), or so on.

In some embodiments, power P1 may be transmitted from the redistribution structure 30 to the carrier 10 through the surface 10s1 of the carrier 10. In some embodiments, power P1 may be transmitted from the carrier 10 to the electronic component 20 through the surface 20s1 of the electronic component 20.

In some embodiments, signal S1 may be transmitted from the electronic component 20, the redistribution structure 50, the conductive element 64, and the redistribution structure 30. The arrows of the power P1 and signal S1 may indicate the transmission path.

FIG. 1B is a partial enlarged view of the electronic device 1a shown in FIG. 1A according to some embodiments of the present disclosure. In some embodiments, the carrier 10 may be bonded to the electronic component 20 by a hybrid-bond technique. The hybrid-bond technique may involve bonding including at least two materials. In some embodiments, the electronic device 1a may include a hybrid-bonding structure 26 between the carrier 10 and the electronic component 20. The hybrid-bonding structure 26 may include pads 27, pads 28, and a dielectric material 29. The pad 27 may abut the surface 10s2 of the carrier 10. The pad 28 may abut the surface 20s1 of the electronic component 20. The pad 27 and pad 28 may be embedded within the dielectric material 29. In some embodiments, the pad 27 may be slightly misaligned with the pad 28. The pad 27 and pad 28 may include copper, tin, aluminum, gold, silver, tungsten, nickel, a combination thereof or other suitable materials. The dielectric material 29 may include silicon oxide, silicon nitride, or other suitable materials.

FIG. 1C is a partial enlarged view of the electronic device 1a shown in FIG. 1A according to some embodiments of the present disclosure. In some embodiments, the carrier 10 may include a barrier layer 14. The barrier layer 14 may be configured to separate the conductive element 13 from the substrate 11. At least a portion of the conductive element 13 may be spaced apart from the substrate 11 by the barrier layer 14. In some embodiments, the barrier layer 14 may include a dielectric material, a conductive material, and a combination thereof. For example, the barrier layer 14 may include silicon oxide, titanium, and other suitable materials.

In some embodiments, the surface 10s1 of the carrier 10 and the surface 40s1 of the encapsulant 40 may be ground or polished. As a result, the surface 40s1 of the encapsulant 40 may be misaligned with the surface 10s1 of the carrier 10 because the slurry or etchant has different selectivities towards the substrate 11 of the carrier 10 and the encapsulant 40. In some embodiments, the surface 10s1 of the carrier 10 may be located at an elevation lower than that of the surface 40s1 of the encapsulant 40.

In some embodiments, the conductive element 13 may protrude below the surface 10s1 of the carrier 10 because the slurry or etchant has different selectivities towards the substrate 11 and the conductive element 13. In some embodiments, the conductive structure 32 of the redistribution structure 30 may be in contact with or laterally overlap the surface 13s1 (or side) and surface 13s2 (or side), opposite to the surface 13s1, of the conductive element 13 in a cross-sectional view.

In some embodiments, the conductive element 64 may protrude below the surface 40s1 of the encapsulant 40 because the slurry or etchant has different selectivities towards the encapsulant 40 and the conductive element 64. In some embodiments, the conductive structure 32 of the redistribution structure 30 may be in contact with or laterally overlap the surface 64s1 (or side) and surface 64s2 (or side), opposite to the surface 64s1, of the conductive element 64 in a cross-sectional view. Similarly, the conductive element 64 may protrude over the surface 40s2 of the encapsulant 40 as shown in FIG. 1A.

In some embodiments, a surface 64s3 (or a lower surface or a bottom) of the conductive element 64 may be located at an elevation different from that of a surface 13s3 (or a lower surface or a bottom) of the conductive element 13 with respect to the surface 10s1 of the carrier 10. In some embodiments, the elevation of the surface 13s3 of the conductive element 13 may be lower than that of the surface 64s3 of the conductive element 64 with respect to the surface 10s1 of the carrier 10. In some embodiments, the elevation difference L1 between the surface 64s3 and the surface 13s3 may range between 0.5 μm to about 10 μm, such as 0.5 μm, 1 μm, 2 μm, 3 μm, 5 μm, or 10 μm.

Although FIG. 1C illustrates that the bottom of the barrier layer 14 is substantially aligned with the surface 13s3 of the conductive element 13, the bottom of the barrier layer 14 may be misaligned with the surface 13s3 of the conductive element 13 in other embodiments.

FIG. 1D is a partial enlarged view of the electronic device 1a shown in FIG. 1A according to some embodiments of the present disclosure. In some embodiments, the encapsulant 40 may include fillers 42. In some embodiments, the filler 42 may have a surface 42s1 (or truncated surface) exposed by the surface 40s1 of the encapsulant 40, which is generated by a grinding or polishing technique. In some embodiments, the filler 42 may have a surface 42s2 (or truncated surface) exposed by the surface 40s2 of the encapsulant 40, which is generated by a grinding or polishing technique. In some embodiments, some of the fillers 42, abutting the surface 40s1, may be removed by a grinding or polishing technique, and a recess 43 (or a dimple) may be formed and recessed from the surface 40s1 of the encapsulant 40. In some embodiments, the dielectric structure 31 of the redistribution structure 30 may fill the recess 43. In some embodiments, some of the filler 42, abutting the surface 40s2, may be removed by a grinding or polishing technique, and a recess 44 (or a dimple) may be formed and set back from the surface 40s2 of the encapsulant 40. In some embodiments, the dielectric structure 51 of the redistribution structure 50 may fill the recess 44. In some embodiments, the roughness of the surface 40s1 of the encapsulant 40 may be greater than the roughness of the surface 10s1 of the carrier 10.

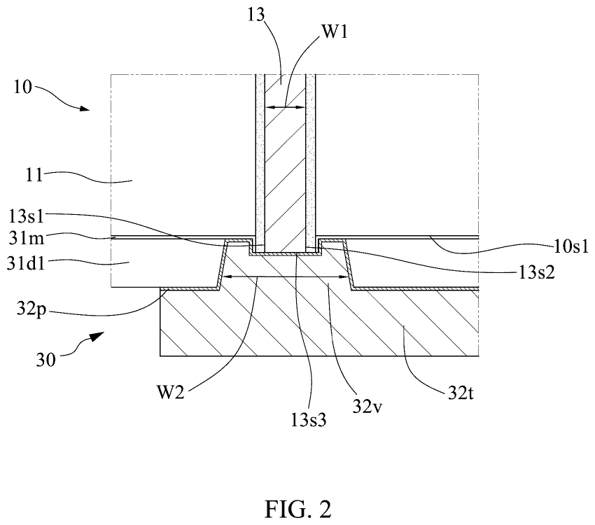

FIG. 2 is a partial enlarged view of the electronic device 1a shown in FIG. 1A according to some embodiments of the present disclosure. In some embodiments, the redistribution structure 30 may include a buffer layer 31m. The buffer layer 31m may cover or be in contact with the surface 10s1 of the carrier 10. The conductive element 13 may be exposed by the buffer layer 31m. The buffer layer 31m may include oxide or other suitable materials. The redistribution structure 30 may include a dielectric layer 31d1. The dielectric layer 31d1 may be spaced apart from the carrier 10 by the buffer layer 31m. The redistribution structure 30 may include a seed layer 32p. The seed layer 32p may be disposed on or under the dielectric layer 31d1. The seed layer 32p may be disposed on or under the buffer layer 31m. The seed layer 32p may be located within the opening defined by the dielectric layer 31d1. The redistribution structure 30 may include a via 32v disposed within the opening defined by the dielectric layer 31d1. The redistribution structure 30 may include a trace 32t connected to the via 32v. The conductive element 13 may have a width W1 (or diameter). The via 32v may have a width W2 (or diameter). In some embodiments, the width W1 may be less than the width W2. The via 32v may laterally overlap or cover the surface 13s1 and surface 13s2 of the conductive element.

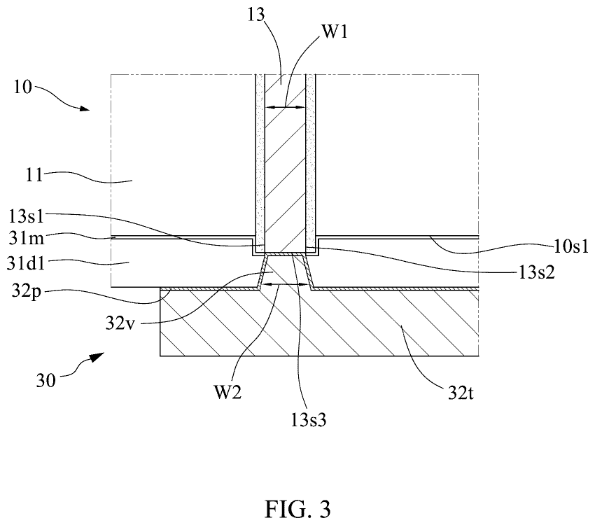

FIG. 3 is a partial enlarged view of the electronic device 1a shown in FIG. 1A according to some embodiments of the present disclosure. In some embodiments, the width W1 may be greater than or substantially equal to the width W2. The via 32v may be free from laterally overlapping the surface 13s1 and surface 13s2 of the conductive element.

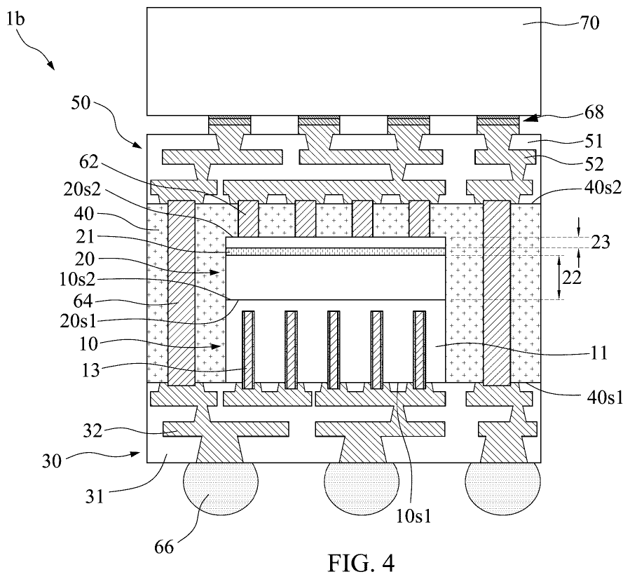

FIG. 4 illustrates a cross-sectional view of an example of an electronic device 1b according to some embodiments of the present disclosure. The electronic device 1b of FIG. 4 has a structure similar to that of the electronic device 1a of FIG. 1A, with differences outlined below.

In some embodiments, the electronic device 1b may include an electronic component 70. The electronic component 70 may be disposed on or over the redistribution structure 50. The electronic component 70 may be electrically connected to the electronic component 20. In some embodiments, the electronic component 70 may be configured to process, store, and/or receive the signal from the electronic component 20. In some embodiments, the electronic component 70 may include a semiconductor die or a chip, such as a memory die, a logic die, a radio frequency die, a sensor die, a micro-electro-mechanical-system die, a signal processing die, a front-end die, or other active components.

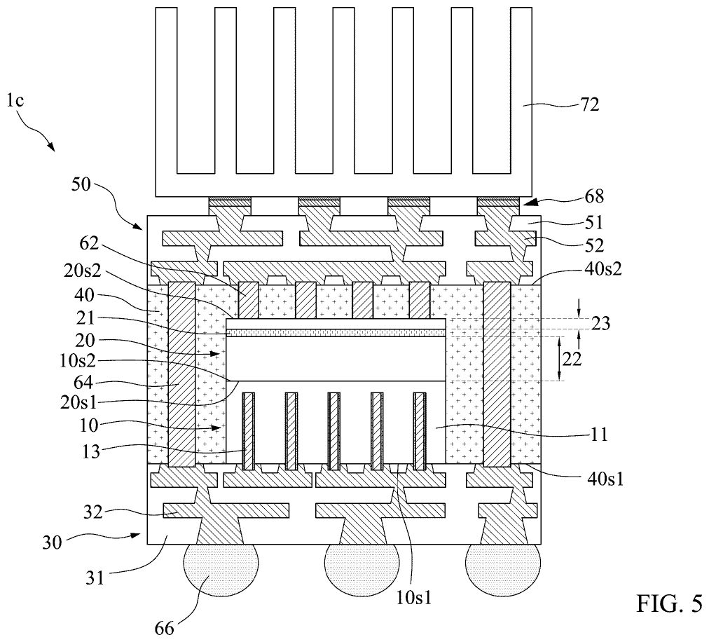

FIG. 5 illustrates a cross-sectional view of an example of an electronic device 1c according to some embodiments of the present disclosure. The electronic device 1c of FIG. 5 has a structure similar to that of the electronic device 1a of FIG. 1A, with differences outlined below.

In some embodiments, the electronic device 1c may include a heat dissipating element 72. The heat dissipating element 72 may be disposed on or over the redistribution structure 50. The heat dissipating element 72 may be configured to dissipate the heat from the electronic device 1c to the surroundings. In some embodiments, the heat dissipating element 72 may include, but is not limited to, a solid metal slug or an electrical insulator coated with metallic film. For example, the heat dissipating element 72 may include copper, aluminum, and/or other suitable materials. The heat dissipating element 72 may also include aluminum oxide, aluminum nitride, or silicon nitride plate coated with copper.

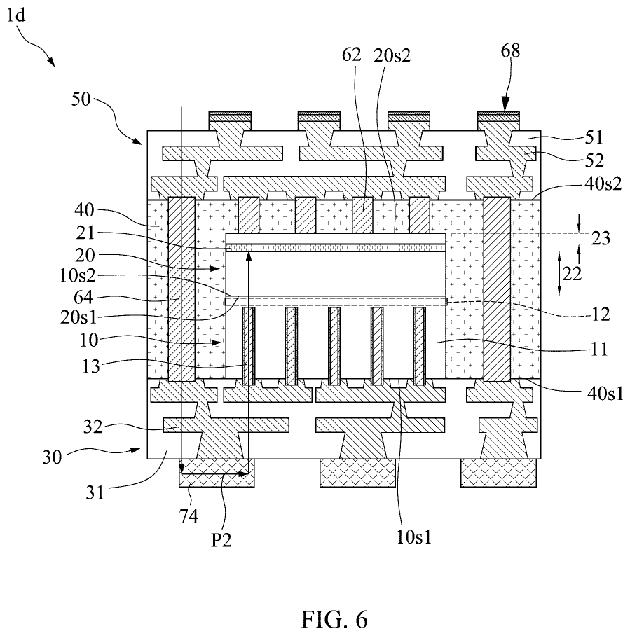

FIG. 6 illustrates across-sectional view of an example of an electronic device 1d according to some embodiments of the present disclosure. The electronic device 1d of FIG. 6 has a structure similar to that of the electronic device 1a of FIG. 1A, with differences outlined below.

In some embodiments, the electronic device 1c may include regulators 74. The regulator 74 may be disposed on or under the redistribution structure 30. The regulator 74 may be configured to regulate power. In some embodiments, the regulator 74 may include a power management IC (PMIC) or other suitable elements. In some embodiments, power P2 may be transmitted through the redistribution structure 50, the conductive element 64, the redistribution structure 30, the regulator 74, the redistribution structure 30, and the carrier 10 in order. In this embodiment, the redistribution structure 30 may be configured to bridge or build a power path between the conductive element 64 and the electronic component 20. In some embodiments, the regulators 74 may provide the electronic component 20 with different powers (or voltages) through the carrier 10.

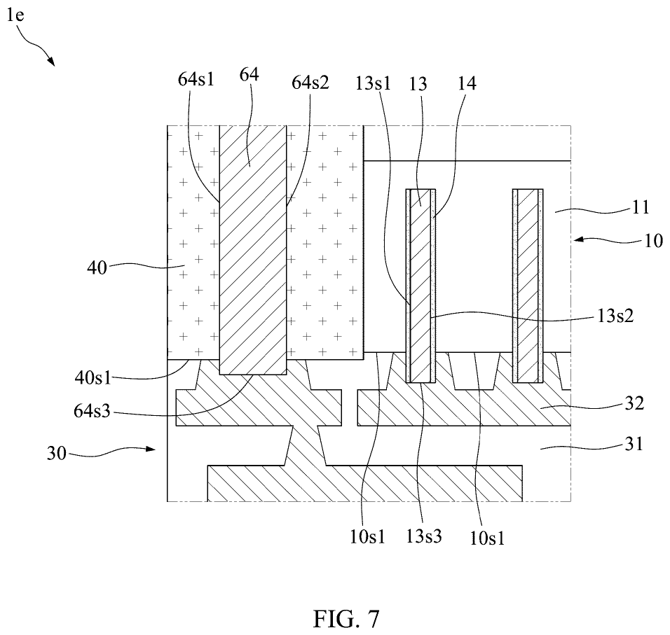

FIG. 7 illustrates a cross-sectional view of an example of an electronic device 1e according to some embodiments of the present disclosure. The electronic device 1e of FIG. 7 has a structure similar to that of the electronic device 1a of FIG. 1C, with the following difference. In some embodiments, the surface 40s1 of the encapsulant 40 may be located at an elevation lower than that of the surface 10s1 of the carrier 10 with respect to the upper surface (e.g., the surface 40s2 shown in FIG. 1) of the encapsulant 40.

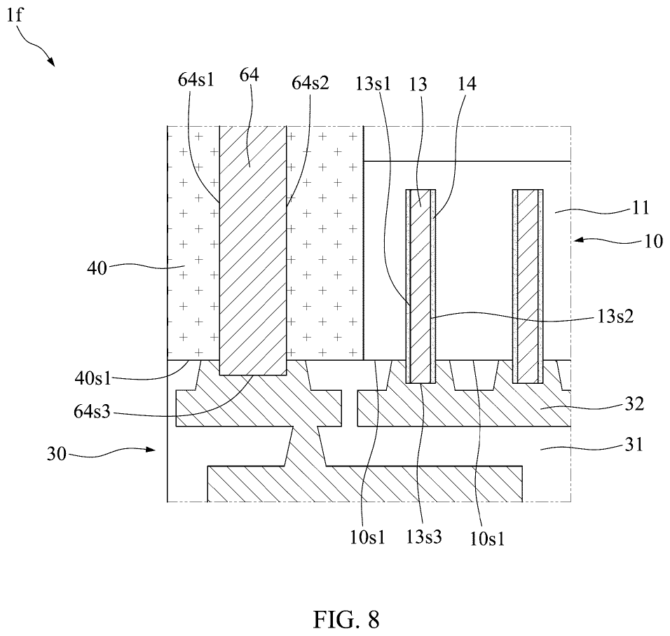

FIG. 8 illustrates a cross-sectional view of an example of an electronic device 1f according to some embodiments of the present disclosure. The electronic device 1f of FIG. 8 has a structure similar to that of the electronic device 1a of FIG. 1C, with the following difference. In some embodiments, the surface 40s1 of the encapsulant 40 may be substantially aligned with the surface 10s1 of the carrier 10.

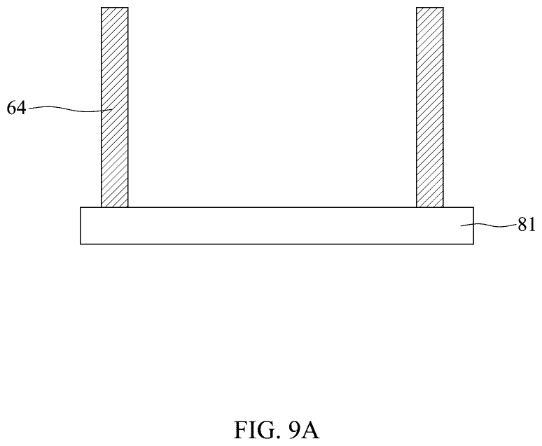

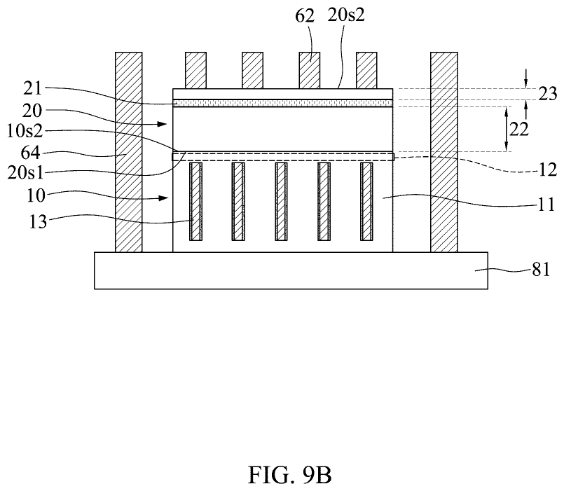

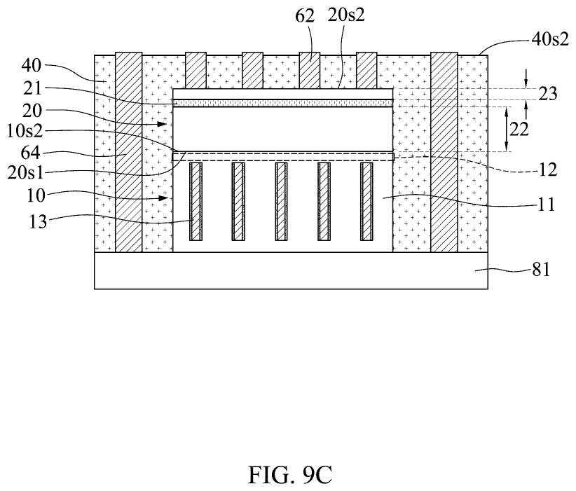

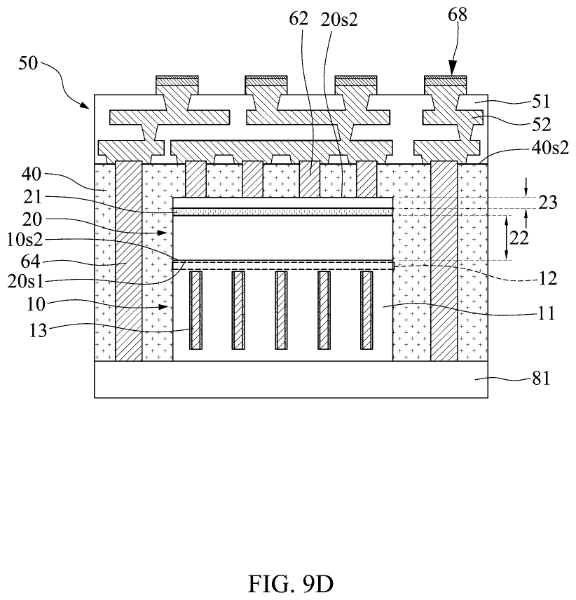

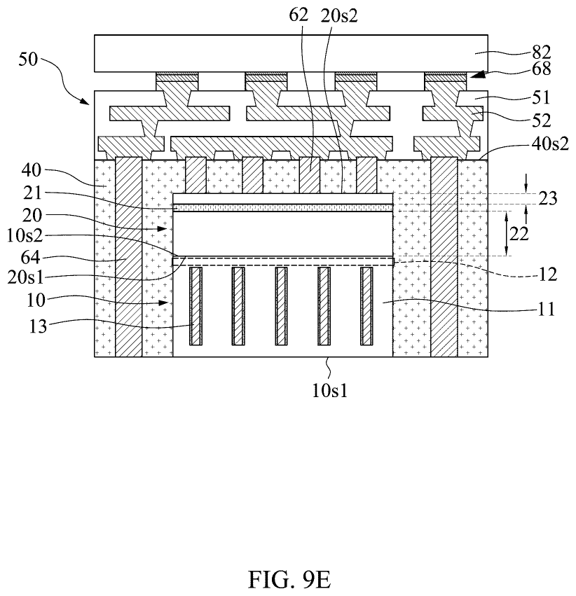

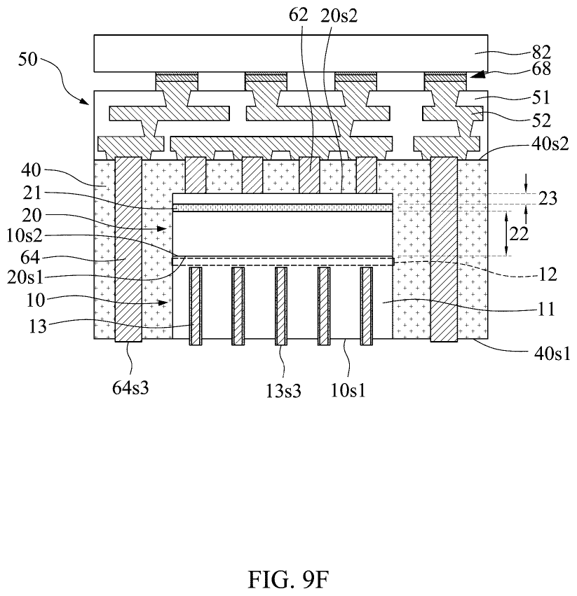

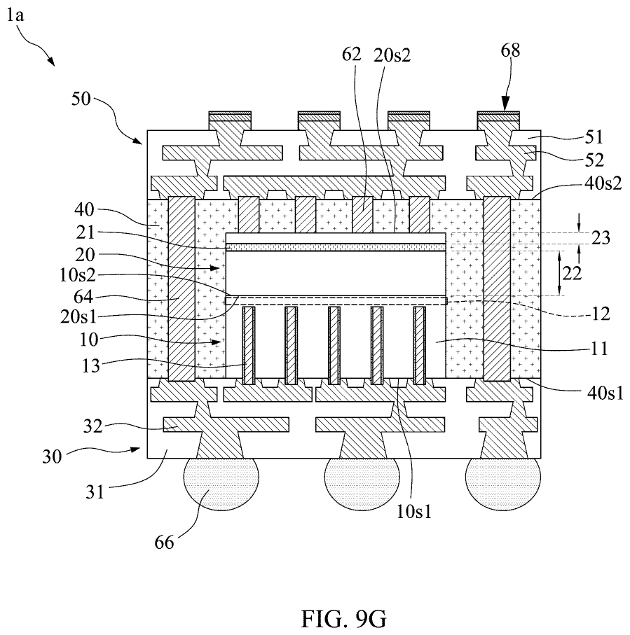

FIGS. 9A, 9B, 9C, 9D, 9E, 9F, and 9G illustrate various stages of an example of a method for manufacturing an electronic device according to some embodiments of the present disclosure.

Referring to FIG. 9A, a supporter 81 may be provided. The supporter 81 may include a glass supporter, a silicon supporter, a plastic supporter, a ceramic supporter, or other suitable supporters. The supporter 81 will be removed in subsequent stages. The conductive element 64 may be formed on or over the supporter 81.

Referring to FIG. 9B, the carrier 10 and the electronic component 20 may be attached to the supporter 81. In some embodiments, the carrier 10 and the electronic component 20 may be initially integrated, and then attached to the supporter 81. The electrical connectors 62 may be pre-formed over the surface 20s2 of the electronic component 20.

Referring to FIG. 9C, the encapsulant 40 may be formed over the supporter 81 to encapsulate the carrier 10, the electronic component 20, and the conductive elements 64. In some embodiments, a grinding or polishing technique may be performed. As a result, the top of the electrical connectors 62 and the conductive elements 64 may be exposed by and/or protrude the surface 40s2 of the encapsulant 40.

Referring to FIG. 9D, the redistribution structure 50 may be formed on or over the encapsulant 40. The redistribution structure 50 may be electrically connected to the conductive element 64 and/or the electrical connector 62.

Referring to FIG. 9E, the supporter 81 may be removed. A supporter 82 may be provided. The redistribution structure 50 may be attached to the supporter 82.

Referring to FIG. 9F, a grinding or polishing technique may be performed on the surface 40s1 of the encapsulant 40 and on the surface 10s1 of the carrier 10. As a result, the conductive elements 64 may be exposed. Since the slurry or etchant has different selectivities towards different materials, the surface 40s1 of the encapsulant 40 may be misaligned with the surface 10s1 of the carrier 10. Further, the surface 64s3 of the conductive element 64 may protrude below the surface 40s1 of the encapsulant 40, and the surface 13s3 (as shown in FIG. 1C) of the conductive element 13 may protrude below the surface 10s1 of the carrier 10.

Referring to FIG. 9G, the redistribution structure 30 may be formed under the carrier 10 and the encapsulant 40. As a result, an electronic device (e.g., the electronic device 1a) may be produced.

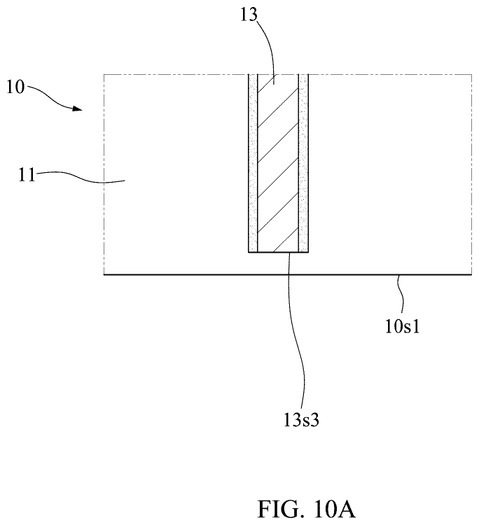

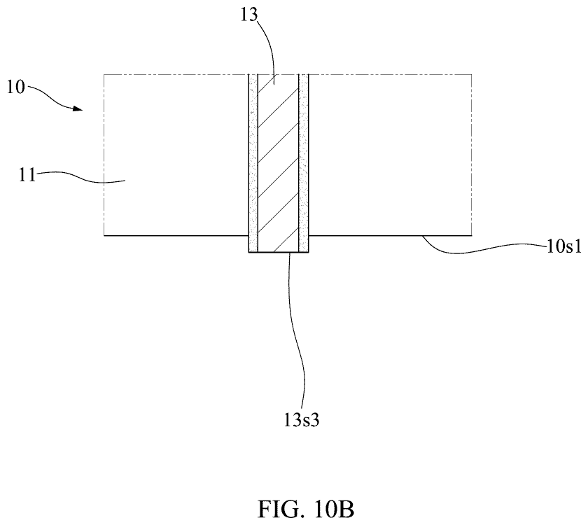

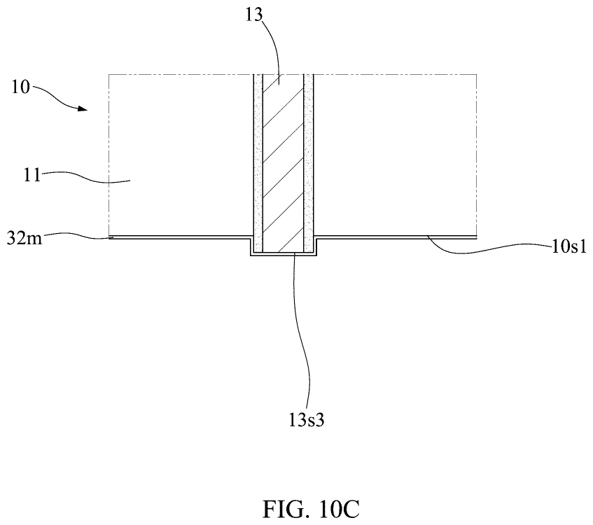

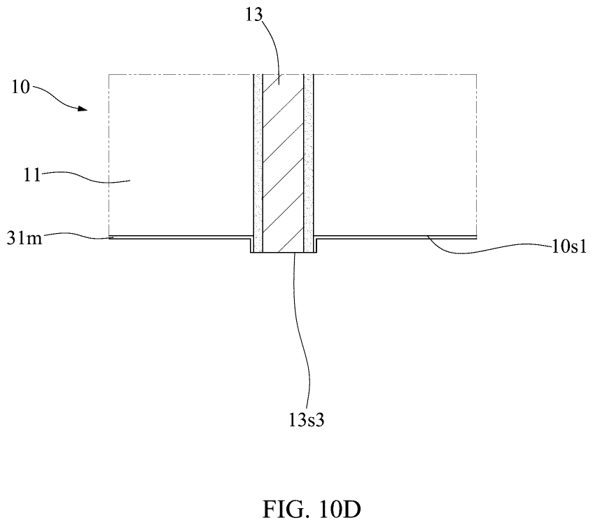

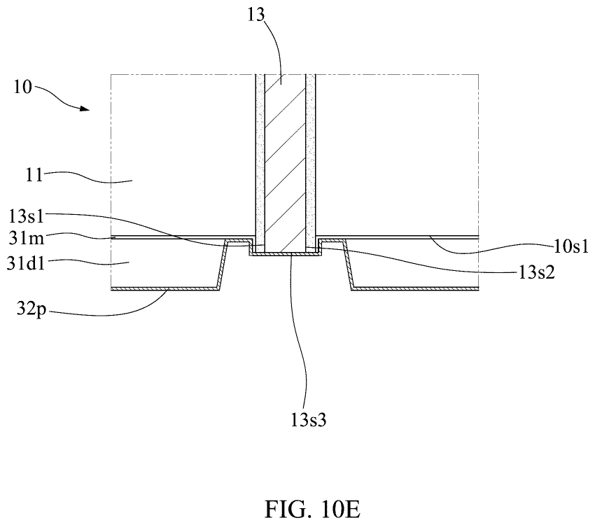

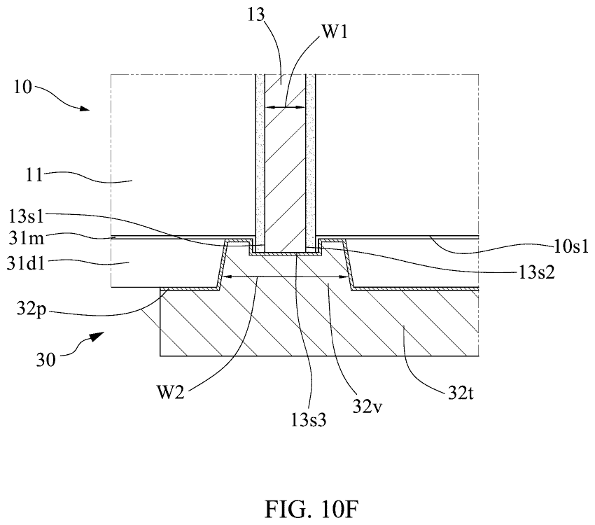

FIGS. 10A, 10B, 10C, 10D, 10E, and 10F illustrate various stages of an example of a method for manufacturing an electronic device according to some embodiments of the present disclosure. FIGS. 10A to 10F illustrate the processes of forming a part of a redistribution structure (e.g., the redistribution structure 30). In some embodiments, FIG. 10A illustrates a stage subsequent to the stage of FIG. 9D.

Referring to FIG. 10A, before performing a grinding or polishing technique, the surface 13s3 of the conductive element 13 may be covered by the substrate 11.

Referring to FIG. 10B, a grinding or polishing technique may be performed on the surface 10s1 of the carrier 10 to expose the surface 13s3 of the conductive element 13. Since the slurry or etchant has different selectivities towards different materials, the surface 10s1 of the carrier 10 may be misaligned with the surface 13s3 of the conductive element 13.

Referring to FIG. 10C, the buffer layer 31m may be formed on or under the substrate 11 and the conductive element 13.

Referring to FIG. 10D, a portion of the buffer layer 31m may be removed to expose the surface 13s3 of the conductive element 13.

Referring to FIG. 10E, the dielectric layer 31d1 may be formed on or under the buffer layer 31m. The dielectric layer 31d1 may be patterned to form an opening exposing the conductive element 13. The seed layer 32p may be formed on the dielectric layer 31d1 and within the opening of the dielectric layer 31d1.

Referring to FIG. 10F, the via 32v and trace 32t may be formed under the buffer layer 31m. A portion of the seed layer 32p, exposed by the trace 32t, may be removed. The stages as shown in FIG. 10A to FIG. 10F may be iterated to produce the redistribution structure 30. Further, the redistribution structure 50 may be produced by processes which are the same as or similar to those depicted in FIG. 10A to FIG. 10F.

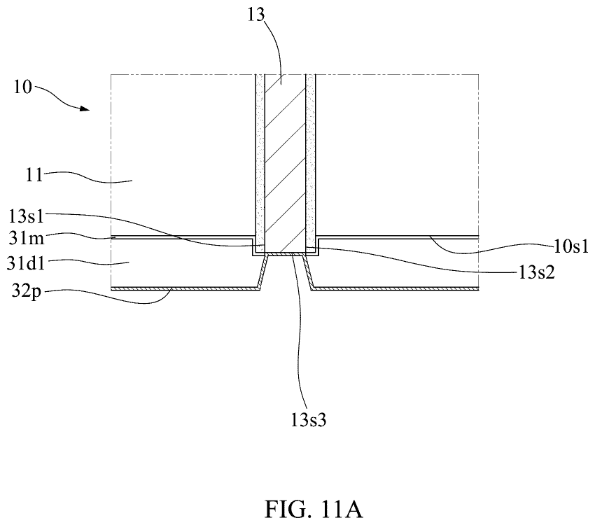

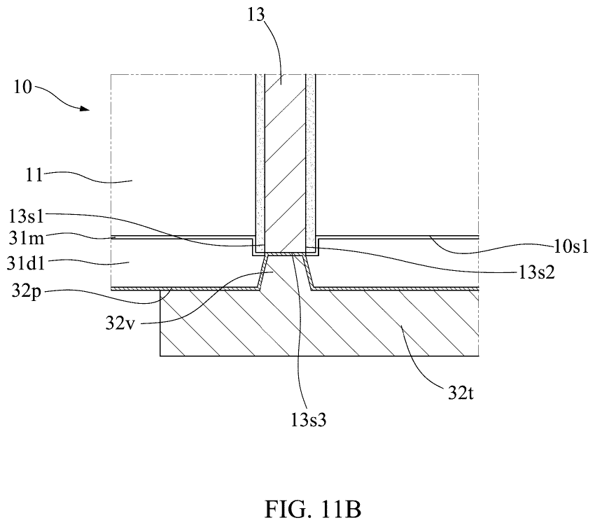

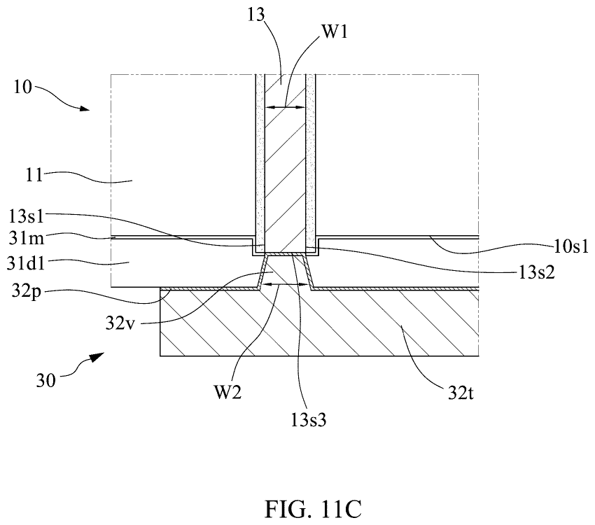

FIGS. 11A, 11B, and 11C illustrate various stages of an example of a method for manufacturing an electronic device according to some embodiments of the present disclosure. The initial stage of the illustrated process is the same as, or similar to, the stage illustrated in FIG. 10A and FIG. 10C. FIG. 11A depicts a stage subsequent to that depicted in FIG. 10C.

Referring to FIG. 11A, the dielectric layer 31d1 may be formed on or under the buffer layer 31m. The dielectric layer 31d1 and the buffer layer 31m may be patterned to form an opening exposing the conductive element 13. Next, the seed layer 32p may be formed on the dielectric layer 31d1 and within the opening defined by the dielectric layer 31d1 and the buffer layer 31m.

Referring to FIG. 11B, the via 32v and trace 32t may be formed under the buffer layer 31m.

Referring to FIG. 11C, a portion of the seed layer 32p, exposed by the trace 32t, may be removed. The stages as shown in FIG. 11A to FIG. 11C may be iterated to produce the redistribution structure 30.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier having a first conductive element exposed by a lower surface of the carrier;
an electronic component disposed over the carrier and configured to receive a power from the first conductive element; and
a second conductive element disposed at a lateral side of the carrier and protruding downwardly below the lower surface of the carrier.

2. The electronic device of claim 1, wherein the electronic component has an upper surface, and the second conductive element protrudes upwardly over the upper surface of the electronic component.

3. The electronic device of claim 1, wherein a diameter of the second conductive element is greater than a diameter of the first conductive element.

4. The electronic device of claim 1, further comprising:
a redistribution structure disposed below the carrier and the second conductive element, wherein the redistribution structure is configured to bridge a power path between the second conductive element and the electronic component.

5. The electronic device of claim 4, wherein the redistribution structure is connected to opposite two sides of the first conductive element in a cross-sectional view.

6. The electronic device of claim 4, wherein the redistribution structure is connected to two opposite sides of the second conductive element in a cross-sectional view.

7. The electronic device of claim 1, wherein the first conductive element protrudes downwardly below the lower surface of the carrier.

8. The electronic device of claim 1, wherein a distance between an elevation of the first conductive element and an elevation of the lower surface of the carrier is greater than a distance between an elevation of a bottom of the second conductive element and the elevation of the lower surface of the carrier.

9. The electronic device of claim 1, further comprising:
an encapsulant encapsulating the second conductive element, wherein the second conductive element protrudes downwardly below a lower surface of the encapsulant.

10. The electronic device of claim 9, wherein the lower surface of the encapsulant is lower than the lower surface of the carrier with respect to an upper surface of the encapsulant.

11. The electronic device of claim 9, wherein the first conductive element protrudes downwardly below the lower surface of the encapsulant.

12. The electronic device of claim 1, wherein the electronic component is configured to receive a power through a lower surface of the electronic component.

13. An electronic device, comprising:
a carrier having a first conductive element exposed by a lower surface of the carrier;
an electronic component disposed over the carrier and configured to receive a power from the first conductive element; and
a second conductive element disposed at a lateral side of the carrier, wherein a lower surface of the first conductive element and a lower surface of the second conductive element are in different elevations with respect to the lower surface of the carrier.

14. The electronic device of claim 13, wherein the carrier comprises a passive component configured to transmit a power to the electronic component through a lower surface of the electronic component.

15. The electronic device of claim 13, further comprising:
an encapsulant encapsulating the second conductive element and the carrier, wherein a roughness of a lower surface of the encapsulant is different from a roughness of the lower surface of the second conductive element.

16. The electronic device of claim 15, wherein the lower surface of the encapsulant is misaligned with the lower surface of the carrier.

17. The electronic device of claim 15, further comprising:
a first redistribution structure disposed under the lower surface of the encapsulant, the encapsulant defines a recess recessed from the lower surface, and a dielectric material of the first redistribution structure is disposed within the recess defined by the encapsulant.

18. An electronic device, comprising:
a passive component;
an electronic component having an active surface and a backside surface configured to receive a power from the passive component;
a first redistribution structure directly connected to the passive component; and
a second redistribution structure directly connected to the active surface of the electronic component.

19. The electronic device of claim 18, further comprising:
an encapsulant disposed between the first redistribution structure and the second redistribution structure.

20. The electronic device of claim 19, wherein the encapsulant comprises a plurality of fillers, and at least one filler has a truncated surface exposed by an upper surface or a lower surface of the encapsulant.
